(19) United States
(12) Patent Application Publication
(10) Pub. No.: US 2026/0304720 A1
(43) Pub. Date: Oct. 1, 2026

(54) INTEGRATED ELECTROMAGNETIC INTERFERENCE SHIELD

(71) Applicant: STMicroelectronics International N.V., Geneva (CH)

(72) Inventors: Fraser Williams, Edinburgh (GB); Marco Antonelli, Edinburgh (GB)

(21) Appl. No.: 19/091,181

(22) Filed: Mar. 26, 2025

(51) Int. Cl. H05K 9/00; H05K 1/18

(52) U.S. Cl. CPC H05K 9/0024; H05K 1/181

(57) ABSTRACT

Methods, systems, and apparatuses for assembling and grounding integrated electromagnetic interference (EMI) shields are provided. An externally grounded external shield can, of an electronic device, may comprise a substrate comprising one or more ground pads at a plurality of respective locations of the substrate for grounding the external shield can, wherein the substrate defines one or more holes or chamfers at the respective locations. The external shield can may define apertures of predetermined sizes corresponding to one or more optical components of the electronic device. The external shield can may define a region of a predetermined threshold minimum size between the external shield can and the cap, wherein the region may be configured to be an airgap.

### TECHNOLOGICAL FIELD

Example embodiments of the present disclosure relate generally to assembling and grounding integrated electromagnetic interference (EMI) shield cans.

### BACKGROUND

Electromagnetic interference shielding creates a Faraday cage effect which attenuates radiation of electromagnetic (EM) waves and/or prevents EM emissions from circuit components such as optical sensors from being emitted outside of the circuit board. Conductive metal cans, commonly fabricated through stamping and/or drawing sheets of metallic material, create a conductive envelopment around the host circuit board containing the optical sensor. These conventional manners of manufacturing, including circuit board level metal can shielding may introduce issues such as an increase in overall footprint of the shielded circuit board. Due to the manufacturing process of stamped metal sheet cans, there is a minimum radius of the corner of the cans, which increases the footprint of the EMI shield. Additionally, using multiple metal cans to cover irregularly shaped components can introduce points through which EM waves may leak, particularly at higher frequencies. Circuit board level metal can shielding, in some examples, does not prevent internal EMI crosstalk between components within the same EMI shield. Additionally, using circuit board level shielding incurs costs in terms of quality assurance to ensure proper assembly and grounding, the process of assembling the shields, and material costs for shielding elements. Furthermore, circuit board level shielding methods have been ineffective, in some examples, at protecting against EMI from the sides of the module substrate itself.

The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to assembling and grounding integrated electromagnetic interference (EMI) shield cans.

In accordance with some embodiments of the present disclosure, an example system is provided. In some embodiments, the system comprises: (i) an electronic device comprising at least one optical module, the at least one optical module comprising one or more optical components, wherein the electronic device comprises one or more electronic components; and (ii) an electrically grounded external shield can, further comprising: a substrate comprising one or more ground pads at a plurality of locations of the substrate for grounding the external shield can, wherein the substrate defines one or more holes or chamfers at the respective locations; wherein the external shield can defines apertures of predetermined sizes corresponding to the one or more optical components; and wherein the external shield can defines a region of a predetermined threshold minimum size between the external shield can and the cap, and wherein the region is configured to be an airgap.

In some embodiments, the external shield can is coupled to the substrate at the respective locations via solder.

In some embodiments, one or more outer edges of the at least one optical module are defined by the cap.

In some embodiments, a subassembly of the at least one optical module is defined by the cap, the substrate, or a combination thereof.

In some embodiments, one or more edges of the external shield can protrude past a first surface of the substrate and towards a second surface of the substrate, wherein the first surface is opposite the second surface, and wherein a distance between the first surface and the second surface defines a thickness of the substrate.

In some embodiments, the one or more edges of the external shield can: (i) overlap at least a portion of the thickness of the substrate; or (ii) overlap at least the full thickness of the substrate.

In some embodiments, a perimeter of the external shield can define at least two dimensions of the at least one optical module, wherein the two dimensions comprise at least: (i) a length of the at least one optical module; or (ii) a width of the at least one optical module.

In accordance with some embodiments of the present disclosure, an example apparatus is provided. In some embodiments, a substrate comprising one or more ground pads at a plurality of locations of the substrate for grounding the external shield can, wherein the substrate defines one or more holes or chamfers at the respective locations; wherein the external shield can defines apertures of predetermined sizes corresponding to one or more optical components of an electronic device; and wherein the external shield can defines a region of a predetermined threshold minimum size between the external shield can and the cap, and wherein the region is configured to be an airgap.

In some embodiments, the external shield can is coupled to the substrate at the respective locations via solder.

In some embodiments, one or more outer edges of the at least one optical module are defined by the cap.

In some embodiments, one or more edges of the external shield can protrude past a first surface of the substrate and towards a second surface of the substrate, wherein the first surface is opposite the second surface, and wherein a distance between the first surface and the second surface defines a thickness of the substrate.

In some embodiments, the one or more edges of the external shield can: (i) overlap at least a portion of the thickness of the substrate; or (ii) overlap at least the full thickness of the substrate.

In some embodiments, a perimeter of the external shield can defines at least two dimensions of the at least one optical module, wherein the two dimensions comprise at least: (i) a length of the at least one optical module; or (ii) a width of the at least one optical module.

In accordance with some embodiments of the present disclosure, an example method is provided. In some embodiments, the method comprises: (i) defining one or more holes or chamfers at a plurality of locations of a substrate; (ii) disposing one or more ground pads at the respective locations of the substrate; (iii) defining, on an external shield can, apertures of predetermined sizes; and (iv) coupling the external shield can to the substrate at the one or more ground pads using solder such that the external shield can is externally grounded; wherein the substrate is coupled to an electronic device comprising at least one optical module and one or more electronic components.

In some embodiments, one or more outer edges of the at least one optical module are defined by the cap.

In some embodiments, a subassembly of the at least one optical module is defined by the cap, the substrate, or a combination thereof.

In some embodiments, the method further comprises shaping the external shield can such that one or more edges of the external shield can protrude past a first surface of the substrate and towards a second surface of the substrate, wherein the first surface is opposite the second surface, and wherein a distance between the first surface and the second surface defines a thickness of the substrate.

In some embodiments, the one or more edges of the external shield can: (i) overlap at least a portion of the thickness of the substrate; or (ii) overlap at least the full thickness of the substrate.

In some embodiments, at least two dimensions of the at least one optical module are defined based on a perimeter of the external shield can, wherein the two dimensions comprise at least: (i) a length of the at least one optical module; or (ii) a width of the at least one optical module.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates a perspective view of an exemplary EMI shield can in accordance with one or more embodiments of the present disclosure.

FIG. 2 illustrates a perspective view of an exemplary substrate in accordance with one or more embodiments of the present disclosure.

FIG. 3 illustrates a perspective view of an exemplary subassembly in accordance with one or more embodiments of the present disclosure.

FIG. 4A illustrates a perspective view of an exemplary EMI shield can in accordance with one or more embodiments of the present disclosure.

FIG. 4B illustrates a cross-sectional view of an exemplary EMI shield can in accordance with one or more embodiments of the present disclosure.

FIG. 5 illustrates a perspective view of an exemplary EMI shield can in accordance with one or more embodiments of the present disclosure.

FIG. 6 illustrates a top-down view of an exemplary EMI shield can in accordance with one or more embodiments of the present disclosure.

FIG. 7 illustrates an example flowchart of operations for assembling a device with EMI shielding in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

### Overview

Various embodiments of the present disclosure are directed to assembling and grounding integrated electromagnetic interference (EMI) shield cans. Various embodiments may include EMI shields, which may be comprised of metal cans, plastic cans, and/or other materials. Various embodiments may include EMI shielding for electronic devices, for example, such as electronic devices which include optical components.

Various embodiments may include EMI shields, for example, such as EMI shield cans. In some embodiments, an EMI shield can is electrically grounded via connection with at least a portion of a device (e.g., via connection with a substrate of an electronic device). In some embodiments, the EMI shield can may surround one or more components of the electronic device such that the EMI shield can is externally grounded. In some embodiments, the electrically grounded external EMI shield can may be at least partially (e.g., fully) integrated into a module (e.g., an optical module of an electronic device). In some examples, such integration may eliminate manufacturing steps, streamlining and/or reducing cost of the fabrication process of devices including electrically grounded external EMI shield cans. In some embodiments, a perimeter of the electrically grounded external EMI shield can may define the outline or footprint of the optical module, which may, in some examples, allow for a wide range of handling during the manufacturing process due to the absence of a protruding substrate. In some embodiments, the electrically grounded external EMI shield can may surround one or more components of the optical module, which may, in some examples, reduce risk of detachment of the EMI shield can during thermal cycling. In some embodiments, the electrically grounded external EMI shield can may at least partially (e.g., fully) cover a thickness of the substrate, wherein the thickness is defined is a distance between a first surface and a second surface of the substrate, wherein the first surface and the second surface are opposite one another. In some examples, such covering of the thickness of the substrate may improve EMI shielding arising from the enclosed components.

Various embodiments may include using a portion of the optical module substrate and/or the circuit board substrate (e.g., which protrudes past the optical module) as a location for grounding pad(s) to which the EMI shield is grounded. Various embodiments may include the EMI shield covering at least a portion of the thickness of the optical module substrate, which may attenuate EM radiation that may leak out through the substrate thickness itself.

The present disclosure, in some examples, includes a number of advantages, including attenuating EMI leakage from the substrate thickness itself via overhanging portions of EMI shields, grounding EMI shields for EMI mitigation, and/or various other advantages.

### Exemplary Systems and Apparatuses

Embodiments of the present disclosure herein include systems and apparatuses for assembling and grounding integrated EMI shield cans, which are described herein and may be implemented in various embodiments.

In some embodiments, EMI shields, for example, such as an externally grounded integrated EMI shield cans may be coupled to devices such as electronic devices. In some embodiments, an EMI shield can may be coupled to a substrate. For example, the EMI shield can may be an external can such that it encloses one or more components of an electronic device to which it is coupled. In this example, at least a portion of a substrate of the electronic device may be a printed circuit board (PCB). The external EMI shield can may be soldered to the PCB substrate. In some embodiments, the external EMI shield can may be coupled to a module substrate, wherein the module is an optical module (e.g., and/or any other type of module) of the electronic device.

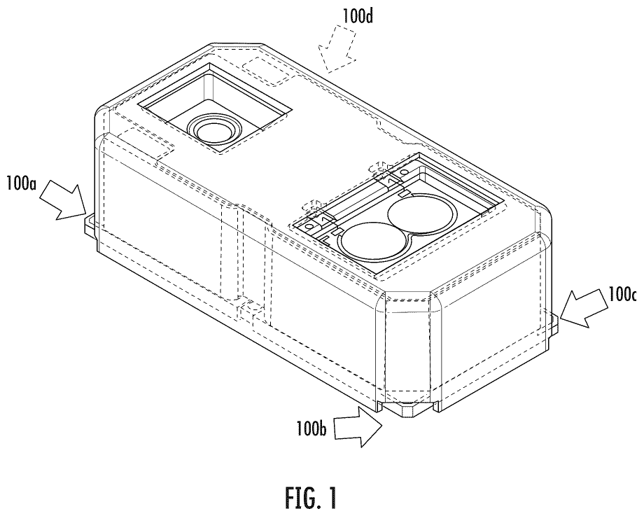

Referring now to FIG. 1, an illustration of a perspective view of an exemplary EMI shield can is provided. As illustrated in FIG. 1, the EMI shield can is coupled to a substrate at a plurality of locations, in particular for this example, at four corners 100a, 100b, 100c, and 100d (collectively “100”) of the substantially rectangular substrate. While the example of FIG. 1 shows a substrate having four corners and shows the EMI shield can coupled to the substrate at those four corners, this is not intended to be limiting. Rather, it should be understood that a substrate may have any number of locations, (e.g., corners, protruding portions, and/or the like) at which an EMI shield can may be coupled. Therefore, the corners 100 may represent 100a . . . N locations, corners, and/or protruding portions.

In some embodiments, the EMI shield can may be coupled to the substrate at the corners 100 using solder. Soldering the EMI shield can to the substrate may yield various advantages, for example, such as improving reliability and/or durability of the connection.

In some embodiment, at least some portions of the locations 100 may be the only portions of the substrate which are not covered by the EMI shield can.

In some embodiments, the EMI shield can may define a region of a predetermined threshold minimum size between the EMI shield can and a cap. The predetermined threshold minimum size may be defined by a height, a width, a length, a volume, and/or the like. The cap may be a component shaped substantially similarly to the EMI shield can which is disposed between the EMI shield can and the electronic, optical, and/or other components of the electronic device. The region of predetermined threshold minimum size between the EMI shield can and the cap may be configured to be an airgap and/or otherwise open to the environment surrounding the electronic device. Configuring a region between the EMI shield can and the cap to be an airgap may yield various advantages, for example, such as allowing for uneven expansion of various components of the electronic device while maintaining the structure of the electronic device. Another advantage of configuring the airgap to be open to the environment, in some examples, is avoiding, preventing, and/or otherwise reducing build-up of internal pressure during thermal cycling (e.g., by allowing free flow to the environment via the airgap).

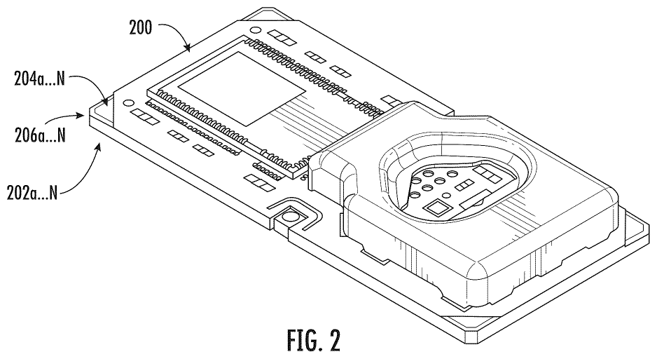

Referring now to FIG. 2, an illustration of a perspective view of an exemplary substrate 200 is provided. As described herein, a substrate may have a plurality of locations (e.g., corners, protruding portions, and/or the like). In the example of FIG. 2, the substrate 200 defines four corners 202a . . . N (collectively “202”). In some embodiments, one or more ground pads 204a . . . N (collectively “204”) may be disposed at respective corners 202 of the substrate 200. For example, one ground pad 204 may be located at each respective corner 202. In some embodiments, the one or more ground pads 204 may be patterned, printed, and/or otherwise disposed on the substrate 200. In some embodiments, the corners 202 may define one or more holes or chamfers 206a . . . N (collectively “206”) at respective corners 202 of the substrate 200. Shaping the corners of the substrate to define holes and/or chamfers may yield various advantages, for example, such as eliminating sharp points.

In some embodiments, one or more of the corners 202 may be at least partially exposed to the environment (e.g., one or more of the corners 202 may be at least partially uncovered by an EMI shield can). Similarly, in some embodiments, one or more of the ground pads 204 may be at least partially exposed to the environment (e.g., one or more of the ground pads 204 may be at least partially uncovered by the EMI shield can). In some embodiments, one or more of the corners 202 and/or one or more of the ground pads 204 may be the only portions of the substrate which are exposed to the environment and/or uncovered by the EMI shield can. Advantages of reducing the amount of surface area of the substrate (e.g., the substrate itself, the ground pads, and/or the like) that remains uncovered by the EMI shield can may include reducing EM radiation escaping the module/device.

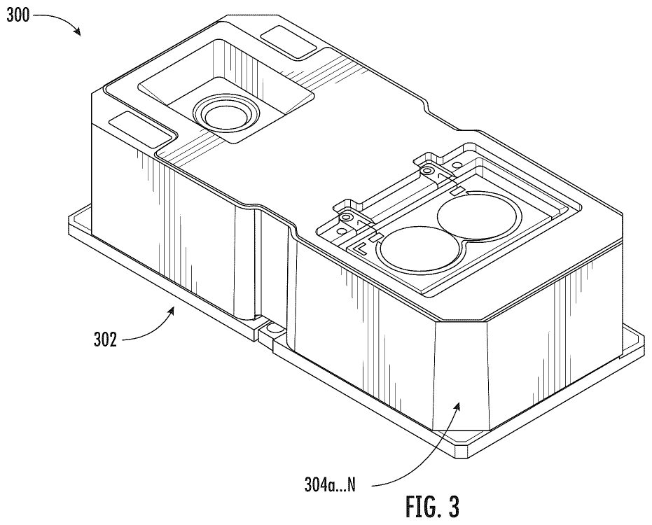

Referring now to FIG. 3, an illustration of a perspective view of an exemplary subassembly 300 is provided. The subassembly 300 may be at least a portion of an electronic device. For example, the subassembly 300 may include an optical module, a substrate 302 corresponding to the optical module, and an EMI shield can defining one or more cavities 304a . . . N (collectively “304”). In some embodiments, one or more outer edges of the optical module and/or the PCB may be defined by a cap. For example, a footprint of the optical module may be defined by the cap. As described herein, the cap may be a component shaped substantially similarly to the EMI shield can which is disposed between the EMI shield can and the electronic, optical, and/or other components of the electronic device. A region of predetermined threshold minimum size between the EMI shield can and the cap may be configured to be an airgap and/or otherwise open to the environment surrounding the subassembly 300. Configuring a region between the EMI shield can and the cap to be an airgap may yield various advantages, for example, such as allowing for uneven expansion of various components of the electronic device while maintaining the structure of the electronic device. Another advantage of configuring the airgap to be open to the environment, in some examples, is avoiding, preventing, and/or otherwise reducing build-up of internal pressure during thermal cycling (e.g., by allowing free flow to the environment via the airgap).

In some embodiments, the cap and the substrate (and/or other components) may define the subassembly 300. For example, the subassembly 300 may include the optical module and the EMI shield, wherein the EMI shield defines the one or more cavities 304. The one or more cavities 304 may yield various advantages, for example, such as allowing for coupling and/or grounding of the EMI shield to the substrate of the electronic device.

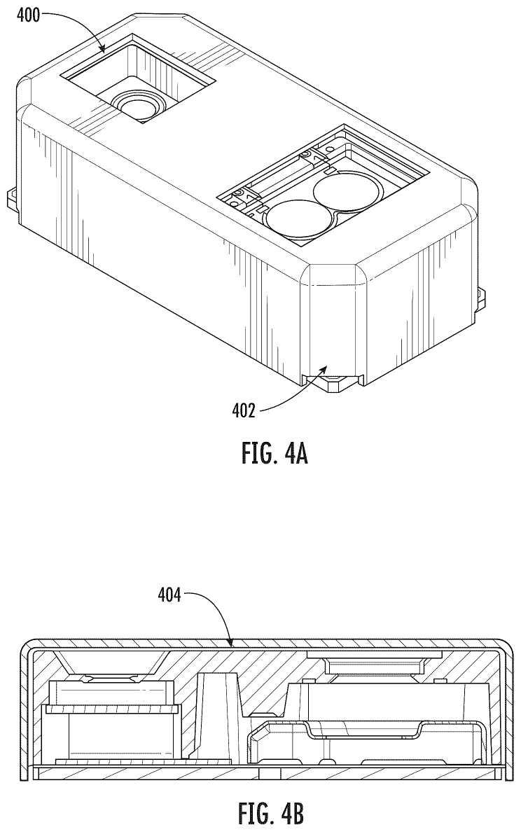

FIGS. 4A-4B illustrate various views of an exemplary EMI shield can. Referring now to FIG. 4A, an illustration of a perspective view of an exemplary EMI shield can is provided. In the example of FIG. 4A, the EMI shield can may be positioned along at the substrate using one or more fiducials on the cap. The one or more fiducials may be aligned with one or more features of a substrate. In some embodiments, solder may be used at the one or more coupling locations (e.g., corners, protruding portions, and/or the like) to couple the EMI shield can to the substrate. In some embodiments, solder reflow may be performed during this portion of the module and/or device assembly. In some embodiments, one or more external aperture sizes 400 may be optically optimized, for example, to reduce and/or eliminate optical clipping during device or module operation.

Referring now to FIG. 4B, an illustration of a cross-sectional view of an exemplary EMI shield can is provided. In some embodiments, a predetermined threshold minimum air gap 404 between the EMI shield can and cap may be defined. As described herein, configuring the region between the EMI shield can and the cap to be an airgap may yield various advantages, for example, such as allowing for uneven expansion of various components of the electronic device while maintaining the structure of the electronic device.

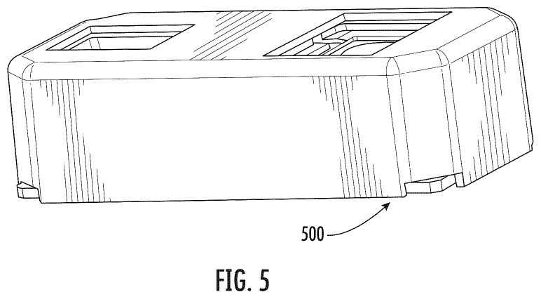

Referring now to FIG. 5, an illustration of a perspective view of an exemplary EMI shield can is provided. In some embodiments, one or more edges of the EMI shield can may protrude past a first surface of the substrate and towards a second surface of the substrate, creating a skirt overlapping at least a portion of a thickness 500 of the substrate. In these embodiments, the thickness 500 of the substrate is defined as the distance between the first surface and the second surface.

In some embodiments, portions of the substrate comprising ground pads and solder for coupling the EMI shield can to the substrate may be the only portions of the substrate left uncovered by the EMI shield can. In some embodiments, the “skirt” may overlap only a portion of the thickness 500 of the substrate (e.g., leaving a predetermined fraction of the thickness uncovered.

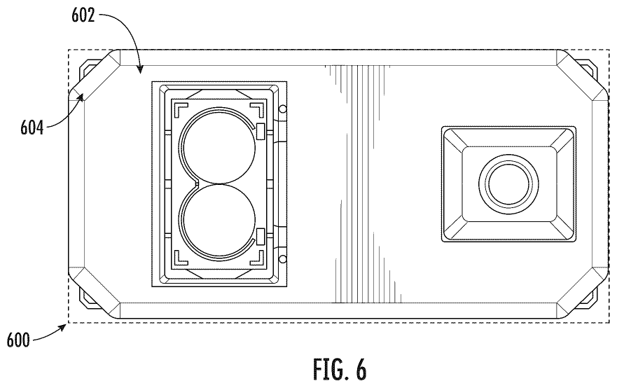

Referring now to FIG. 6, an illustration of a top-down view of an exemplary EMI shield can in accordance with one or more embodiments of the present disclosure. In some embodiments, one or more outer edges of the EMI shield (e.g., as defined by an outer perimeter 600 of the EMI shield). In some embodiments, the outer perimeter defines X- and Y-dimensions of the optical module and/or the electronic device. In some embodiments, the substrate extends only as far as the X- and Y-boundaries of the optical module and/or the electronic device.

### Exemplary Methods

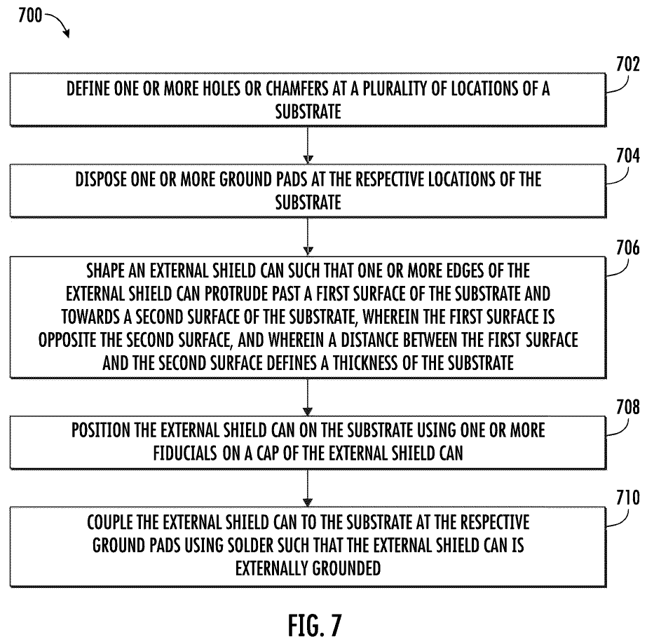

FIG. 7 illustrates an example flow chart for a method 700 of assembling a device including an EMI shield can. It should be understood that the steps/operations illustrated in FIG. 7 and the example ordering of the steps/operations are not intended to be limiting. In some embodiments, one or more of the steps/operations may be reordered and/or repeated. In some embodiments, one or more of the step/operations may be partially or fully omitted.

At step/operation 702, one or more holes or chamfers may be defined at a plurality of locations of a substrate. For example, as described with respect to FIGS. 1-6, four holes or chamfers may be defined at four corners of a substantially rectangular substrate.

At step/operation 704, one or more ground pads may be disposed at the respective locations of the substrate. For example, the one or more ground pads may be printed, patterned, and/or the like onto the substrate at the respective locations.

At step/operation 706, an external EMI shield can may be shaped such that one or more edges of the external EMI shield can may protrude past a first surface of the substrate and towards a second surface of the substrate. The first surface of the substrate may be opposite the second surface of the substrate such that a distance between the first surface and the second surface may define a thickness of the substrate.

At step/operation 708, the external EMI shield can may be positioned on the substrate using one or more fiducials on a cap of the external shield can. For example, the cap may define one or more fiducials thereon, and the external EMI shield can may be positioned on the substrate by aligning the one or more fiducials of the can with one or more respective features of the substrate. In some embodiments, step/operation 708 may be optionally performed.

At step/operation 710, the external EMI shield can may be coupled to the substrate at the respective ground pads. For example, the external EMI shield can may be coupled to the substrate at the respective ground pads using solder, thereby grounding the external EMI shield can.

### CONCLUSION

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a computer-implemented process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A system comprising:
an electronic device comprising at least one optical module, the at least one optical module comprising one or more optical components, wherein the electronic device comprises one or more electronic components; and
an electrically grounded external shield can, further comprising:
a substrate comprising one or more ground pads at a plurality of locations on the substrate for grounding the external shield can, wherein the substrate defines one or more holes or chamfers at the respective locations;
wherein the external shield can defines apertures of predetermined sizes corresponding to the one or more optical components; and
wherein the external shield can defines a region of a predetermined threshold minimum size between the external shield can and the cap, and wherein the region is configured to be an airgap.

2. The system of claim 1, wherein the external shield can is coupled to the substrate at the respective locations via solder.

3. The system of claim 1, wherein one or more outer edges of the at least one optical module are defined by the cap.

4. The system of claim 1, wherein a subassembly of the at least one optical module is defined by the cap, the substrate, or a combination thereof.

5. The system of claim 1, wherein one or more edges of the external shield can protrude past a first surface of the substrate and towards a second surface of the substrate, wherein the first surface is opposite the second surface, and wherein a distance between the first surface and the second surface defines a thickness of the substrate.

6. The system of claim 5, wherein the one or more edges of the external shield can:
overlap at least a portion of the thickness of the substrate; or
overlap at least the full thickness of the substrate.

7. The system of claim 1, wherein a perimeter of the external shield can defines at least two dimensions of the at least one optical module, wherein the two dimensions comprise at least:
a length of the at least one optical module; or
a width of the at least one optical module.

8. An apparatus comprising:
a substrate comprising one or more ground pads at a plurality of locations of the substrate for grounding the external shield can, wherein the substrate defines one or more holes or chamfers at the respective locations;
wherein the external shield can defines apertures of predetermined sizes corresponding to one or more optical components of an electronic device; and
wherein the external shield can defines a region of a predetermined threshold minimum size between the external shield can and the cap, and wherein the region is configured to be an airgap.

9. The apparatus of claim 8, wherein the external shield can is coupled to the substrate at the respective locations via solder.

10. The apparatus of claim 8, wherein one or more outer edges of the at least one optical module are defined by the cap.

11. The apparatus of claim 8, wherein a subassembly of the at least one optical module is defined by the cap, the substrate, or a combination thereof.

12. The apparatus of claim 8, wherein one or more edges of the external shield can protrude past a first surface of the substrate and towards a second surface of the substrate, wherein the first surface is opposite the second surface, and wherein a distance between the first surface and the second surface defines a thickness of the substrate.

13. The apparatus of claim 12, wherein the one or more edges of the external shield can:
overlap at least a portion of the thickness of the substrate; or
overlap at least the full thickness of the substrate.

14. The apparatus of claim 8, wherein a perimeter of the external shield can defines at least two dimensions of the at least one optical module, wherein the two dimensions comprise at least:
a length of the at least one optical module; or
a width of the at least one optical module.

15. A method for fabricating an external shield can, the method comprising:
defining one or more holes or chamfers at a plurality of locations of a substrate;
disposing one or more ground pads at the respective locations of the substrate;
defining, on an external shield can, apertures of predetermined sizes; and
coupling the external shield can to the substrate at the respective ground pads using solder such that the external shield can is externally grounded;
wherein the substrate is coupled to an electronic device comprising at least one optical module and one or more electronic components.

16. The method of claim 15, wherein one or more outer edges of the at least one optical module are defined by the cap.

17. The method of claim 15, wherein a subassembly of the at least one optical module is defined by the cap, the substrate, or a combination thereof.

18. The method of claim 15, further comprising:
shaping the external shield can such that one or more edges of the external shield can protrude past a first surface of the substrate and towards a second surface of the substrate, wherein the first surface is opposite the second surface, and wherein a distance between the first surface and the second surface defines a thickness of the substrate.

19. The method of claim 18, wherein the one or more edges of the external shield can:
overlap at least a portion of the thickness of the substrate; or
overlap at least the full thickness of the substrate.

20. The method of claim 15, wherein a perimeter of the external shield can defines at least two dimensions of the at least one optical module, wherein the two dimensions comprise at least:
a length of the at least one optical module; or
a width of the at least one optical module.
